(19) United States
(12) Patent Application Publication
(10) Pub. No.: US 2023/0137029 A1
(43) Pub. Date: May 4, 2023

(54) PHOTOSENSITIVE DEVICE

(71) Applicant: Au Optronics Corporation, Hsinchu (TW)

(72) Inventors: Chih-Chung Su, Hsinchu (TW); Shin-Shueh Chen, Hsinchu (TW)

(73) Assignee: Au Optronics Corporation, Hsinchu (TW)

(21) Appl. No.: 17/742,370

(22) Filed: May 11, 2022

(30) Foreign Application Priority Data
Nov. 1, 2021 (TW) 110140624

(51) Int. Cl. G06V 40/13; H01L 27/146; G06V 40/40

(52) U.S. Cl. CPC G06V 40/1318; H01L 27/14623; H01L 27/14627; H01L 27/14678; G06V 40/40

(57) ABSTRACT

A photosensitive device includes a substrate, an active element layer, a first photosensitive element and a second photosensitive element. Each first photosensitive element includes a first lower conductive structure, a first photosensitive layer, and a first upper conductive structure stacked in sequence. Each second photosensitive element includes a second lower conductive structure, a second photosensitive layer, and a second upper conductive structure stacked in sequence. The first upper conductive structure includes an opaque electrode or a semi-transparent electrode, and the second upper conductive structure includes a transparent electrode. The first upper conductive structure is configured to make a signal difference between a photocurrent signal and a dark current signal of the first photosensitive element smaller than a signal difference between a photocurrent signal and a dark current signal of the second photosensitive element.

### CROSS-REFERENCE TO RELATED APPLICATION

This application claims the priority benefit of Taiwan application serial no. 110140624, filed on Nov. 1, 2021. The entirety of the above-mentioned patent application is hereby incorporated by reference herein and made a part of this specification.

### BACKGROUND

### Technical Field

The disclosure relates to a photosensitive device, and more particularly, to a photosensitive device including multiple photosensitive elements.

### Description of Related Art

At present, in order to increase the security of products, many manufacturers install fingerprint recognition sensing devices in their products. In the existing fingerprint recognition technology, the sensing device detects the light reflected by the fingerprint of the finger, and the uneven surfaces of the fingerprint cause reflected light of different intensities, so the different fingerprint appearances are distinguished by the sensing device. Generally speaking, a sensing device for fingerprint recognition includes photosensitive elements arranged in an array. The uneven surfaces of the fingerprint at different positions are detected by the photosensitive elements arranged in an array to obtain the overall appearance of the fingerprint.

### SUMMARY

The disclosure provides a photosensitive device which has an anti-counterfeiting function and can improve the reliability of fingerprint recognition.

At least an embodiment of the disclosure provides a photosensitive device. The photosensitive device includes a substrate, an active element layer, a first photosensitive element, and a second photosensitive element. The active element layer is located above the substrate. Each first photosensitive element includes a first lower conductive structure, a first photosensitive layer, and a first upper conductive structure stacked in sequence. The first lower conductive structure is electrically connected to the active element layer. Each second photosensitive element includes a second lower conductive structure, a second photosensitive layer, and a second upper conductive structure stacked in sequence. The second lower conductive structure is electrically connected to the active element layer. The first upper conductive structure includes an opaque electrode or a semi-transparent electrode. The second upper conductive structure includes a transparent electrode. The first upper conductive structure is configured so that a signal difference between a photocurrent signal and a dark current signal of the at least one first photosensitive element is smaller than a signal difference between a photocurrent signal and a dark current signal of the at least one second photosensitive element.

At least an embodiment of the disclosure provides a photosensitive device. The photosensitive device includes a substrate, an active element layer, a first photosensitive element, and a second photosensitive element. The active element layer is located above the substrate. Each first photosensitive element includes a first lower conductive structure, a first photosensitive layer, and a first upper conductive structure stacked in sequence. The first lower conductive structure is electrically connected to the active element layer. Each second photosensitive element includes a second lower conductive structure, a second photosensitive layer, and a second upper conductive structure stacked in sequence. The second lower conductive structure is electrically connected to the active element layer. The first lower conductive structure includes a transparent electrode. The second lower conductive structure includes an opaque electrode. The first lower conductive structure is configured so that a signal difference between a photocurrent signal and a dark current signal of the at least one first photosensitive element is smaller than a signal difference between a photocurrent signal and a dark current signal of the at least one second photosensitive element.

At least an embodiment of the disclosure provides a photosensitive device. The photosensitive device includes a substrate, an active element layer, a first photosensitive element, and a second photosensitive element. The active element layer is located above the substrate. Each first photosensitive element includes a first lower conductive structure, a first photosensitive layer, and a first upper conductive structure stacked in sequence. The first lower conductive structure is electrically connected to the active element layer. Each second photosensitive element includes a second lower conductive structure, a second photosensitive layer, and a second upper conductive structure stacked in sequence. The second lower conductive structure is electrically connected to the active element layer. A first shielding structure is an opaque structure or a semi-transparent structure, and the first shielding structure overlaps the first photosensitive element and does not overlap the second photosensitive element. The first shielding structure is configured so that a signal difference between a photocurrent signal and a dark current signal of the at least one first photosensitive element is smaller than a signal difference between a photocurrent signal and a dark current signal of the at least one second photosensitive element.

Based on the above, by reducing the difference between the photocurrent signal and the dark current signal of the first photosensitive element, the photosensitive device has an anti-counterfeiting function, thereby improving the reliability of fingerprint recognition.

### BRIEF DESCRIPTION OF THE DRAWINGS

FIG. 1 is a schematic cross-sectional view of a photosensitive device according to an embodiment of the disclosure.

FIG. 2 is a schematic top view of a photosensitive device according to an embodiment of the disclosure.

FIG. 3 is a schematic cross-sectional view of a photosensitive device according to an embodiment of the disclosure.

FIG. 4 is a schematic cross-sectional view of a photosensitive device according to an embodiment of the disclosure.

FIG. 5 is a voltage-current graph of the photosensitive device of FIG. 4.

FIG. 6 is an output voltage-time graph of the photosensitive device of FIG. 4.

FIG. 7 is a schematic cross-sectional view of a photosensitive device according to an embodiment of the disclosure.

FIG. 8 is a voltage-current graph of the photosensitive device of FIG. 7.

FIG. 9 is a schematic cross-sectional view of a photosensitive device according to an embodiment of the disclosure.

FIG. 10 is a voltage-current graph of the photosensitive device of FIG. 9.

FIG. 11 is a schematic cross-sectional view of a photosensitive device according to an embodiment of the disclosure.

FIG. 12 is a voltage-current graph of the photosensitive device of FIG. 11.

FIG. 13 is a schematic top view of a photosensitive device according to an embodiment of the disclosure.

FIG. 14 is a schematic cross-sectional view taken along line a-a′ of FIG. 13.

### DESCRIPTION OF EMBODIMENTS

In the disclosure, relative terms such as “below” or “bottom” and “above” or “top” may serve to describe the relation between one element and another element in the text according to the illustration of the drawings. It should also be understood that the relative terms are intended to include different orientations of a device in addition to the orientation shown in the drawings. For example, if a device in the accompanying drawings is flipped, an element described as being on the “lower” side of other elements shall be re-orientated to be on the “upper” side of other elements. Thus, the exemplary term “lower” may cover the orientations of “upper” and “lower”, depending on the specific orientations of the accompanying drawings. Similarly, if a device in the accompanying drawings is flipped, an element described as being “below” other elements shall be re-orientated to be “above” other elements. Thus, the exemplary term “above” or “below” may cover the orientations of above and below.

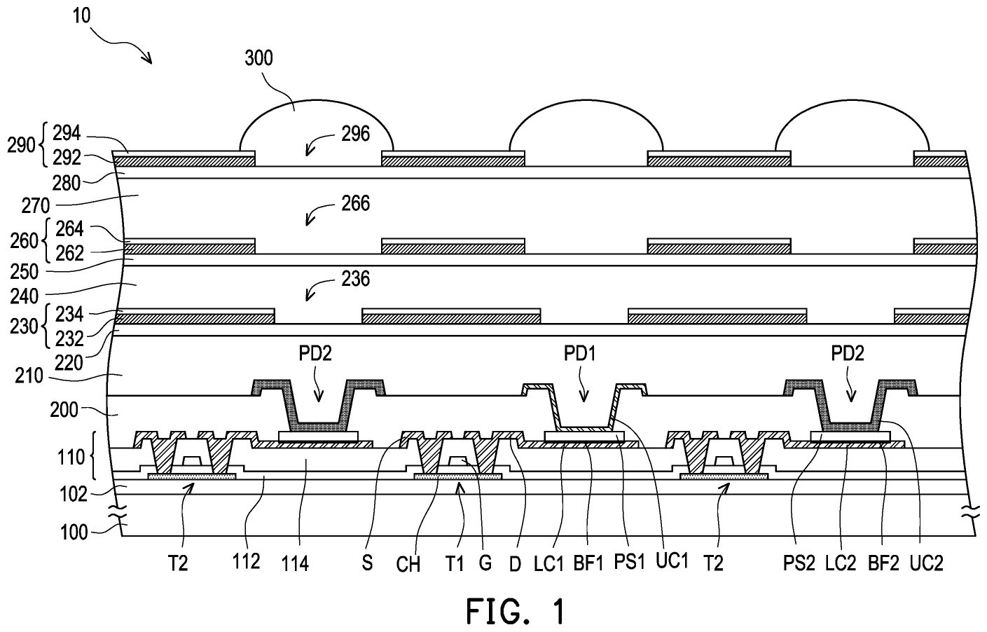

FIG. 1 is a schematic cross-sectional view of a photosensitive device according to an embodiment of the disclosure.

Please refer to FIG. 1. A photosensitive device 10 includes a substrate 100, an active element layer 110, at least one first photosensitive element PD1 and at least one second photosensitive element PD2. In this embodiment, the photosensitive device 10 further includes a first collimating structure 230, a second collimating structure 260, a third collimating structure 290 and a lens element 300. It should be noted that, in FIG. 1, the number of photosensitive elements and the number of active elements are only used for illustration, but not for limiting the disclosure. In other words, the number of photosensitive elements and the number of active elements may be adjusted according to actual needs.

The material of the substrate 100 includes glass, quartz, organic polymers, or opaque/reflective materials (for example, conductive materials, metals, wafers, ceramics, or other applicable materials) or other applicable materials. If a conductive material or metal is used, an insulating layer (not shown) is coated on the substrate 100 to avoid the short circuit problem.

The active element layer 110 is located above the substrate 100. In this embodiment, a buffer layer 102 is optionally included between the active element layer 110 and the substrate 100. The active element layer 110 includes multiple active elements. For example, the active element layer 110 includes multiple first active elements T1 and multiple second active elements T2. The first active element T1 and the second active element T2 are bottom gate type thin film transistors, top gate type thin film transistors, double gate type thin film transistors or other types of thin film transistors. In this embodiment, the first active element T1 and the second active element T2 are top gate type thin film transistors.

In this embodiment, the first active element T1 and the second active element T2 each include a gate G, a channel CH, a source S, and a drain D. The channel CH overlaps the gate G, and a gate insulating layer 112 is sandwiched between the channel CH and the gate G. An interlayer dielectric layer 114 is located on the gate G and the gate insulating layer 112. The source S and the drain D are located on the interlayer dielectric layer 114 and are electrically connected to the channel CH through a conductive hole penetrating the gate insulating layer 112 and the interlayer dielectric layer 114.

In some embodiments, the material of the channel CH includes amorphous silicon, polycrystalline silicon, microcrystalline silicon, monocrystalline silicon, organic semiconductor materials, oxide semiconductor materials (for example, indium zinc oxide, indium gallium zinc oxide or other suitable materials or combinations of the above) or other suitable materials or combinations of the above. The materials of the gate G, the source S and the drain D include chromium, gold, silver, copper, tin, lead, hafnium, tungsten, molybdenum, neodymium, titanium, tantalum, aluminum, zinc and other metals, alloys of the above metals, oxides of the above metals, nitride of the above metals, or combinations of the above or other conductive materials.

In this embodiment, the first active element T1 and the second active element T2 include the same structure, but the disclosure is not limited thereto. In other embodiments, the first active element T1 and the second active element T2 include different structures. For example, the first active element T1 and the second active element T2 include different types of thin film transistors or include thin film transistors made of different materials.

The first photosensitive element PD1 and the second photosensitive element PD2 are electrically connected to the active element layer 110. Each first photosensitive element PD1 includes a first lower conductive structure LC1, a first photosensitive layer PS1, and a first upper conductive structure UC1 stacked in sequence. Each second photosensitive element PD2 includes a second lower conductive structure LC2, a second photosensitive layer PS2, and a second upper conductive structure UC2 stacked in sequence.

In this embodiment, each photosensitive element is electrically connected to a corresponding active element. Specifically, each first photosensitive element PD1 is electrically connected to a corresponding one of the first active elements T1 in the active element layer 110, and each second photosensitive element PD2 is electrically connected to a corresponding one of the second active elements T2 in the active element layer 110.

In this embodiment, the first lower conductive structure LC1 of the first photosensitive element PD1 and the second lower conductive structure LC2 of the second photosensitive element PD2 are electrically connected to the active element layer 110. In this embodiment, the first lower conductive structure LC1 is integrated with the drain D of the corresponding first active element T1, and the second lower conductive structure LC2 is integrated with the drain D of the corresponding second active element T2. In this embodiment, the source S and drain D of the first active element T1, the source S and drain D of the second active element T2, the first lower conductive structure LC1 and the second lower conductive structure LC2 belong to the same conductive layers, and include the same materials, but the disclosure is not limited thereto. In other embodiments, the first lower conductive structure LC1 and the second lower conductive structure LC2 may belong to different conductive layers from the source S and drain D of the first active element T1 and the source S and drain D of the second active element T2. In other words, in other embodiments, the first lower conductive structure LC1 and the second lower conductive structure LC2 may include materials different from the source S and the drain D. In this embodiment, the first lower conductive structure LC1 and the second lower conductive structure LC2 are opaque metal electrodes.

The first photosensitive layer PS1 is located on the first lower conductive structure LC1, and the second photosensitive layer PS2 is located on the second lower conductive structure LC2. In some embodiments, the respective materials of the first photosensitive layer PS1 and the second photosensitive layer PS2 include, for example, silicon-rich nitride, silicon-rich oxynitride, silicon-rich carbide, silicon-rich oxycarbide, hydrogenated silicon-rich oxide, hydrogenated silicon-rich nitride, hydrogenated silicon-rich carbide, or a combination thereof, but the disclosure is not limited thereto. In other embodiments, the first photosensitive layer PS1 and the second photosensitive layer PS2 each include a stacked layer of a P-type semiconductor, an intrinsic semiconductor, and an N-type semiconductor. In this embodiment, the first photosensitive layer PS1 and the second photosensitive layer PS2 include the same material, but the disclosure is not limited thereto.

In some embodiments, a protective layer BF1 and a protective layer BF2 for suppressing dark current signals are formed between the first lower conductive structure LC1 and the first photosensitive layer PS1 and between the metal material of the second lower conductive structure LC2 and the second photosensitive layer PS2, respectively. The protective layer BF1 and the protective layer BF2 are, for example, metal oxides. For example, in some embodiments, the first lower conductive structure LC1 and the second lower conductive structure LC2 each include a stacked structure of titanium, aluminum and titanium. The titanium in the outer layer is oxidized during the manufacturing process, and the protective layer BF1 and the protective layer BF2 including titanium oxide are formed. In other embodiments, the material of the protective layer BF1 and the protective layer BF2 includes molybdenum oxide, and the method for forming the protective layer BF1 and the protective layer BF2 includes a sputtering or water oxidation process.

A first insulating layer 200 is located on the active element layer 110, the first photosensitive layer PS1 and the second photosensitive layer PS2, and has multiple openings overlapping the first photosensitive layer PS1 and the second photosensitive layer PS2. In some embodiments, the first insulating layer 200 includes a single-layer or multi-layer structure, and the material of the first insulating layer 200 includes an organic material or an inorganic material.

The first upper conductive structure UC1 and the second upper conductive structure UC2 are located on the first insulating layer 200 and fill the openings in the first insulating layer 200 to contact the first photosensitive layer PS1 and the second photosensitive layer PS2 respectively. In this embodiment, the material of the first upper conductive structure UC1 is different from the material of the second upper conductive structure UC2, and the first upper conductive structure UC1 includes an opaque electrode or a semi-transparent electrode, and the second upper conductive structure UC2 includes a transparent electrode.

In some embodiments, the first upper conductive structure UC1 includes a semi-transparent or opaque metal. In this embodiment, the first upper conductive structure UC1 includes a semi-transparent metal, such as molybdenum or aluminum with a thickness of less than 500 nm.

In some embodiments, the second upper conductive structure UC2 includes a transparent conductive material, such as indium tin oxide, indium zinc oxide, aluminum tin oxide, aluminum zinc oxide, indium gallium zinc oxide, or a stacked layer of at least two of the above or other materials. In this embodiment, the thickness of the second upper conductive structure UC2 is greater than the thickness of the first upper conductive structure UC1.

A second insulating layer 210 is located on the first photosensitive element PD1 and the second photosensitive element PD2. In some embodiments, the second insulating layer 210 includes a single-layer or multi-layer structure, and the material of the second insulating layer 210 includes an organic material or an inorganic material.

A first buffer layer 220 is located on the second insulating layer 210. In some embodiments, the first buffer layer 220 includes a single-layer or multi-layer structure, and the material of the first buffer layer 220 includes an organic material or an inorganic material.

The first collimating structure 230 is located on the first buffer layer 220. In this embodiment, the first collimating structure 230 is located above the first photosensitive element PD1 and above the second photosensitive element PD2. The first collimating structure 230 has multiple openings 236 overlapping the first photosensitive element PD1 and the second photosensitive element PD2.

The first collimating structure 230 includes a single-layer or multi-layer structure. In this embodiment, the first collimating structure 230 includes a first light shielding layer 232 and a first anti-reflection layer 234 on the first light shielding layer 232. In some embodiments, the first light shielding layer 232 includes a metal (for example, molybdenum), and the first anti-reflection layer 234 includes a metal oxide (for example, molybdenum oxide), but the disclosure is not limited thereto.

A third insulating layer 240 is located on the first collimating structure 230. In some embodiments, the third insulating layer 240 includes a single-layer or multi-layer structure, and the material of the third insulating layer 240 includes an organic material or an inorganic material.

A second buffer layer 250 is located on the third insulating layer 240. In some embodiments, the second buffer layer 250 includes a single-layer or multi-layer structure, and the material of the second buffer layer 250 includes an organic material or an inorganic material.

The second collimating structure 260 is located on the second buffer layer 250. In this embodiment, the second collimating structure 260 is located above the first photosensitive element PD1 and above the second photosensitive element PD2. The second collimating structure 260 has multiple openings 266 overlapping the first photosensitive element PD1 and the second photosensitive element PD2. In this embodiment, the openings 266 of the second collimating structure 260 overlap the openings 236 of the first collimating structure 230, and the width of the openings 266 is greater than or equal to the width of the openings 236.

The second collimating structure 260 includes a single-layer or multi-layer structure. In this embodiment, the second collimating structure 260 includes a second light shielding layer 262 and a second anti-reflection layer 264 on the second light shielding layer 262. In some embodiments, the second light shielding layer 262 includes a metal (for example, molybdenum), and the second anti-reflection layer 264 includes a metal oxide (for example, molybdenum oxide), but the disclosure is not limited thereto.

A fourth insulating layer 270 is located on the second collimating structure 260. In some embodiments, the fourth insulating layer 270 includes a single-layer or multi-layer structure, and the material of the fourth insulating layer 270 includes an organic material or an inorganic material.

A third buffer layer 280 is located on the fourth insulating layer 270. In some embodiments, the third buffer layer 280 includes a single-layer or multi-layer structure, and the material of the third buffer layer 280 includes an organic material or an inorganic material.

The third collimating structure 290 is located on the third buffer layer 280. In this embodiment, the third collimating structure 290 is located above the first photosensitive element PD1 and above the second photosensitive element PD2. The third collimating structure 290 has multiple openings 296 overlapping the first photosensitive element PD1 and the second photosensitive element PD2. In this embodiment, the openings 296 of the third collimating structure 290 overlap the openings 236 of the first collimating structure 230 and the openings 266 of the second collimating structure 260, and the width of the openings 296 is greater than or equal to the width of the openings 266.

The third collimating structure 290 includes a single-layer or multi-layer structure. In this embodiment, the third collimating structure 290 includes a third light shielding layer 292 and a third anti-reflection layer 294 on the third light shielding layer 292. In some embodiments, the third light shielding layer 292 includes a metal (for example, molybdenum), and the third anti-reflection layer 294 includes a metal oxide (for example, molybdenum oxide), but the disclosure is not limited thereto.

Multiple lens elements 300 are located on the third buffer layer 280. In this embodiment, the lens elements 300 are located in the openings 296 of the third collimating structure 290. The lens elements 300 are located above the first photosensitive element PD1 and the second photosensitive element PD2 and overlap the openings 236, the openings 266 and the openings 296. In some embodiments, the lens elements 300 include an organic material or an inorganic material.

In this embodiment, the first photosensitive element PD1 and the second photosensitive element PD2 are adapted for receiving light reflected by a finger. When the light is received, the first photosensitive element PD1 and the second photosensitive element PD2 each generate a corresponding photocurrent signal. When no light is received, the first photosensitive element PD1 and the second photosensitive element PD2 each generate a corresponding dark current signal.

Table 1 compares the differences in the photocurrent signals generated by the first photosensitive element PD1 when different materials and thicknesses of the first upper conductive structure UC1 are used. In Table 1, the comparison is made based on the photocurrent signal being 100% when the first upper conductive structure UC1 is made of transparent indium tin oxide.

TABLE 1

| First upper | | Molybdenum | Molybdenum | Aluminum |
|---|---|---|---|---|
| conductive | Indium | (150 | (300 | (150 |
| structure | tin oxide | angstroms) | angstroms) | angstroms) |
| Photocurrent | 100% | 15.8% | 6.1% | 12.1% |
| signal | | | | |

As may be seen from Table 1, when the first upper conductive structure is made of molybdenum or aluminum with poor light transmittance, the intensity of the photocurrent signal generated by the first photosensitive element PD1 decreases.

Based on the above, under the same amount of light, since the first upper conductive structure UC1 includes an opaque electrode or a semi-transparent electrode, and the second upper conductive structure UC2 includes a transparent electrode, the intensity of the photocurrent signal generated by the first photosensitive element PD1 is smaller than the intensity of the photocurrent signal generated by the second photosensitive element PD2. Therefore, a signal difference I1 between the photocurrent signal and the dark current signal of the first photosensitive element PD1 is smaller than a signal difference I2 between the photocurrent signal and the dark current signal of the second photosensitive element PD2. In other words, the first upper conductive structure UC1 is configured to reduce the signal difference I1 between the photocurrent signal and the dark current signal of the first photosensitive element PD1, so that the signal difference I1 between the photocurrent signal and the dark current signal of the first photosensitive element PD1 is smaller than the signal difference I2 between the photocurrent signal and the dark current signal of the second photosensitive element PD2.

In this embodiment, the difference between the signal difference I1 and the signal difference I2 may be used to identify the authenticity of the fingerprint. For example, the first photosensitive element PD1 and the second photosensitive element PD2 respectively generate the signal difference I1 between the photocurrent signal and the dark current signal and the signal difference I2 between the photocurrent signal and the dark current signal after receiving the light reflected by the finger, and the first photosensitive element PD1 and the second photosensitive element PD2 respectively generate a signal difference I1′ between the photocurrent signal and the dark current signal and a signal difference I2′ between the photocurrent signal and the dark current signal after receiving light reflected from other materials. Since a difference between the signal difference I1 and the signal difference I2 is different from a difference between the signal difference IF and the signal difference I2′, it may be identified whether the light received by the first photosensitive element PD1 and the second photosensitive element PD2 is reflected by the finger or reflected by other materials. Based on the above, the photosensitive device 10 has an anti-counterfeiting function, and the reliability of fingerprint recognition may be improved by the first photosensitive element PD1 and the second photosensitive element PD2.

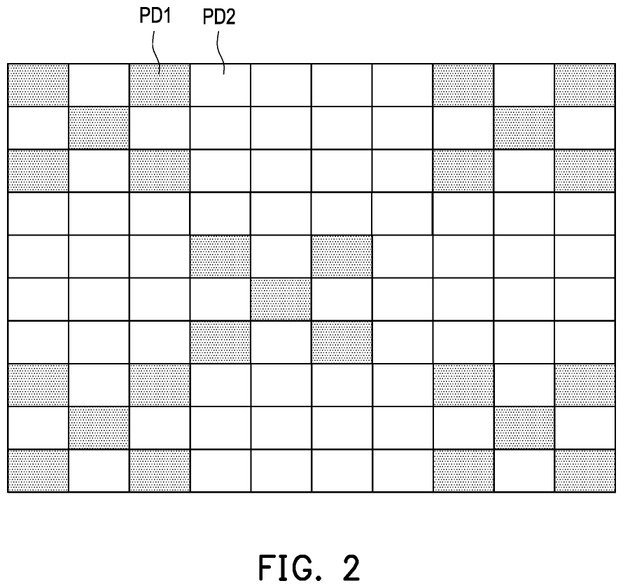

FIG. 2 is a schematic top view of a photosensitive device according to an embodiment of the disclosure. FIG. 2 is used to illustrate the distribution positions of the first photosensitive element PD1 and the second photosensitive element PD2, and FIG. 2 omits the illustration of other structures of the photosensitive device. For the structure of the photosensitive device, please refer to FIG. 1 and the related description of FIG. 1, and details are not repeated here.

Please refer to FIG. 2. In this embodiment, each first photosensitive element PD1 is adjacent to four or more second photosensitive elements PD2. It should be noted that FIG. 2 is only used to illustrate one distribution pattern of the first photosensitive element PD1 and the second photosensitive element PD2. In other embodiments, the first photosensitive element PD1 and the second photosensitive element PD2 may have other distribution patterns.

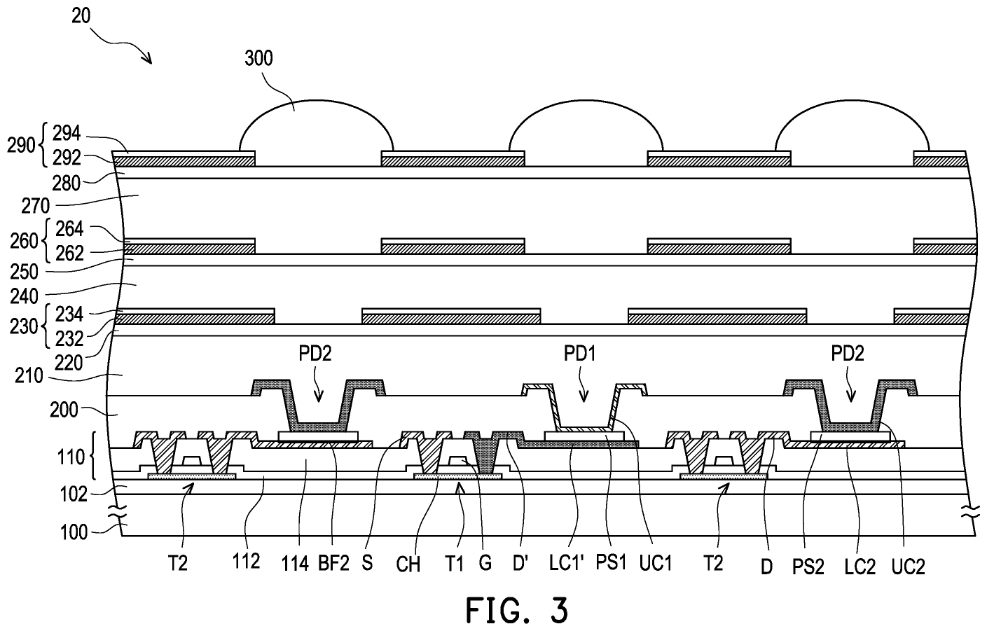

FIG. 3 is a schematic cross-sectional view of a photosensitive device according to an embodiment of the disclosure. It is noted that the embodiment of FIG. 3 uses the reference numerals and a part of the contents of the embodiment of FIG. 1, and the same or similar reference numerals are used to denote the same or similar elements, and the description of the same technical content is omitted. For the description of the omitted part, reference may be made to the foregoing embodiment, and details are not described herein.

The difference between a photosensitive device 20 of FIG. 3 and the photosensitive device 10 of FIG. 1 is that in the photosensitive device 20, the material of the first lower conductive structure LC1′ of the first photosensitive element PD1 is different from the material of the second lower conductive structure LC2 of the second photosensitive element PD2.

In this embodiment, the first lower conductive structure LC1′ of the first photosensitive element PD1 includes a transparent electrode, such as a metal oxide. In this embodiment, the second lower conductive structure LC2 of the second photosensitive element PD2 includes an opaque electrode, such as an opaque metal. In this embodiment, the first lower conductive structure LC1′ is integrated with the drain D′ of the first active element T1, and the materials of the first lower conductive structure LC1′ and the drain D′ of the first active element T1 both Include metal oxides; therefore, the material of the drain D′ of the first active element T1 is different from the material (for example, metal material) of the drain D of the second active element T2, but the disclosure is not limited thereto. In other embodiments, the first lower conductive structure LC1′ is not integrally formed with the drain D′ of the first active element T1, and the material of the first lower conductive structure LC1′ includes metal oxide, and the material of the drain D′ of the first active element T1 includes metal.

In this embodiment, the material of the second lower conductive structure LC2 includes metal, and the material of the first lower conductive structure LC1′ includes metal oxide. Therefore, in the process, the protective layer BF2 is formed between the second lower conductive structure LC2 and the second photosensitive layer PS2, and no protective layer is formed between the first lower conductive structure LC1′ and the first photosensitive layer PS1. The protective layer BF2 is located between the second photosensitive layer PS2 and the second lower conductive structure LC2.

In this embodiment, the first lower conductive structure LC1′ and the first upper conductive structure UC1 are both configured to reduce the signal difference I1 between the photocurrent signal and the dark current signal of the first photosensitive element PD1, so that the signal difference I1 between the photocurrent signal and the dark current signal of the first photosensitive element PD1 is smaller than the signal difference I2 between the photocurrent signal and the dark current signal of the second photosensitive element PD2. In this embodiment, the protective layer BF2 helps to suppress the dark current signal of the second photosensitive element PD2, thereby increasing the signal difference I2 between the photocurrent signal and the dark current signal of the second photosensitive element PD2. In addition, since the first photosensitive element PD1 does not have a protective layer, the signal difference I1 between the photocurrent signal and the dark current signal of the first photosensitive element PD1 may be reduced, thereby increasing the difference between the signal difference I1 and the signal difference I2. In this embodiment, the dark current signal of the first photosensitive element PD1 is greater than the dark current signal of the second photosensitive element PD2.

Based on the above, the photosensitive device 20 has an anti-counterfeiting function, and the reliability of fingerprint recognition may be improved by the first photosensitive element PD1 and the second photosensitive element PD2.

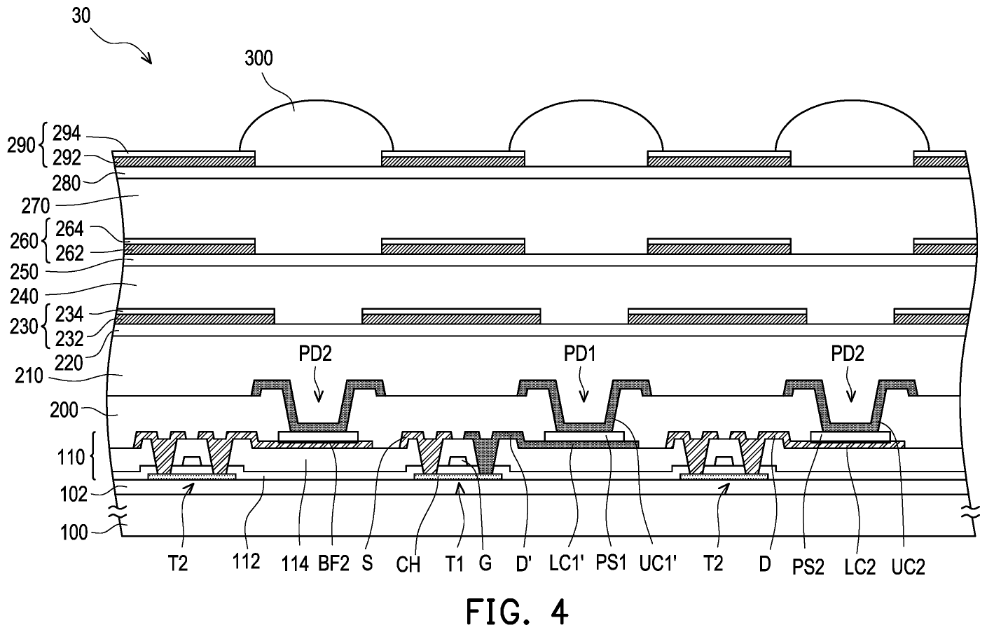

FIG. 4 is a schematic cross-sectional view of a photosensitive device according to an embodiment of the disclosure. It is noted that the embodiment of FIG. 4 uses the reference numerals and a part of the contents of the embodiment of FIG. 3, and the same or similar reference numerals are used to denote the same or similar elements, and the description of the same technical content is omitted. For the description of the omitted part, reference may be made to the foregoing embodiment, and details are not described herein.

The difference between a photosensitive device 30 of FIG. 4 and the photosensitive device 20 of FIG. 3 is that in the photosensitive device 30, the material of the first upper conductive structure UC1′ of the first photosensitive element PD1 is the same as the material of the second upper conductive structure UC2 of the second photosensitive element PD2.

Please refer to FIG. 4. The photosensitive device 30 includes a substrate 100, an active element layer 110, a first photosensitive element PD1 and a second photosensitive element PD2. The active element layer 110 is located above the substrate 100. The active element layer 110 includes multiple first active elements T1 and multiple second active elements T2.

Each first photosensitive element PD1 includes a first lower conductive structure LC1′, a first photosensitive layer PS1, and a first upper conductive structure UC1′ stacked in sequence. The first lower conductive structure LC1′ is electrically connected to the active element layer 110. The first active element T1 of the active element layer 110 is electrically connected to the first lower conductive structure LC1′. Each second photosensitive element PD2 includes a second lower conductive structure LC2, a second photosensitive layer PS2, and a second upper conductive structure UC2 stacked in sequence. The second lower conductive structure LC2 is electrically connected to the active element layer 110. The second active element T2 of the active element layer 110 is electrically connected to the second lower conductive structure LC2.

In this embodiment, the first upper conductive structure UC1′ and the second upper conductive structure UC2 include the same material. In this embodiment, both the first upper conductive structure UC1′ and the second upper conductive structure UC2 include a transparent conductive material, such as indium tin oxide, indium zinc oxide, aluminum tin oxide, aluminum zinc oxide, indium gallium zinc oxide, or a stacked layer of at least two of the above or other materials. In this embodiment, the thickness of the second upper conductive structure UC2 is equal to the thickness of the first upper conductive structure UC1.

In this embodiment, the first lower conductive structure LC1′ of the first photosensitive element PD1 includes a transparent electrode, such as a metal oxide (for example, indium tin oxide, indium zinc oxide, aluminum tin oxide, aluminum zinc oxide, indium gallium zinc oxide, or a stacked layer of at least two of the above or other materials). In this embodiment, the second lower conductive structure LC2 of the second photosensitive element PD2 includes an opaque electrode, such as an opaque metal.

In this embodiment, the second lower conductive structure LC2 includes metal, and the first lower conductive structure LC1′ includes metal oxide. Therefore, in the process, the protective layer BF2 is formed between the second lower conductive structure LC2 and the second photosensitive layer PS2, and no protective layer is formed between the first lower conductive structure LC1′ and the first photosensitive layer PS1.

In this embodiment, the first lower conductive structure LC1′ is configured to reduce the signal difference I1 between the photocurrent signal and the dark current signal of the first photosensitive element PD1, so that the signal difference I1 between the photocurrent signal and the dark current signal of the first photosensitive element PD1 is smaller than the signal difference I2 between the photocurrent signal and the dark current signal of the second photosensitive element PD2. In this embodiment, the protective layer BF2 helps to suppress the dark current signal of the second photosensitive element PD2, thereby increasing the signal difference I2 between the photocurrent signal and the dark current signal of the second photosensitive element PD2. In addition, since the first photosensitive element PD1 does not have a protective layer, the signal difference I1 between the photocurrent signal and the dark current signal of the first photosensitive element PD1 may be reduced, thereby increasing the difference between the signal difference I1 and the signal difference I2. In this embodiment, the dark current signal of the first photosensitive element PD1 is greater than the dark current signal of the second photosensitive element PD2.

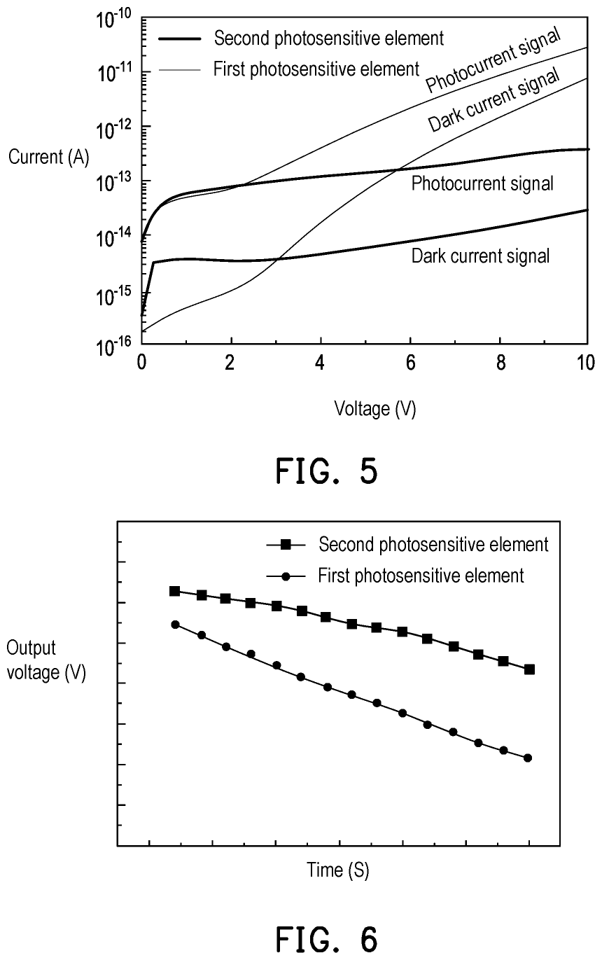

FIG. 5 is a voltage-current graph of the photosensitive device of FIG. 4. FIG. 6 is an output voltage-time graph of the photosensitive device of FIG. 4.

In the embodiments of FIG. 4 to FIG. 6, the first lower conductive structure LC1′ and the first upper conductive structure UC1′ of the first photosensitive element PD1 both include transparent electrodes. The second lower conductive structure LC2 of the second photosensitive element PD2 includes an opaque electrode, and the second upper conductive structure UC2 includes a transparent electrode.

It may be seen from FIG. 5 and FIG. 6 that the signal difference I1 between the photocurrent signal and the dark current signal of the first photosensitive element PD1 is smaller than the signal difference I2 between the photocurrent signal and the dark current signal of the second photosensitive element PD2, and the output voltage of the first photosensitive element PD1 is lower than the output voltage of the second photosensitive element PD2.

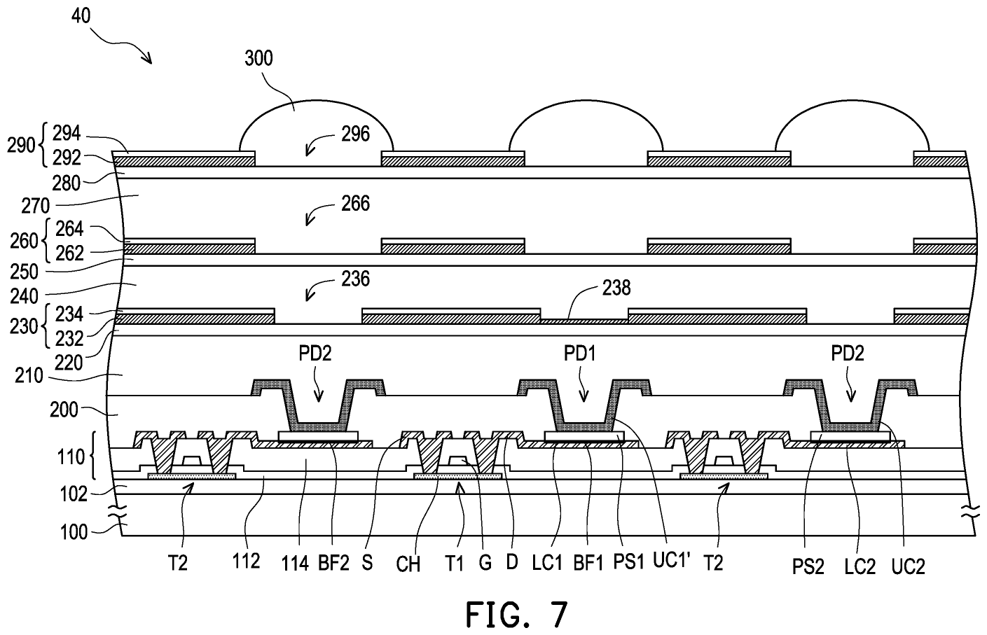

FIG. 7 is a schematic cross-sectional view of a photosensitive device according to an embodiment of the disclosure. It is noted that the embodiment of FIG. 7 uses the reference numerals and a part of the contents of the embodiment of FIG. 1, and the same or similar reference numerals are used to denote the same or similar elements, and the description of the same technical content is omitted. For the description of the omitted part, reference may be made to the foregoing embodiments, and details are not described herein.

The difference between a photosensitive device 40 of FIG. 7 and the photosensitive device 10 of FIG. 1 is that in the photosensitive device 40, the material of the first upper conductive structure UC1′ of the first photosensitive element PD1 is the same as the material of the second upper conductive structure UC2 of the second photosensitive element PD2.

Please refer to FIG. 7. The photosensitive device 40 includes a substrate 100, an active element layer 110, a first photosensitive element PD1 and a second photosensitive element PD2. The active element layer 110 is located above the substrate 100.

Each first photosensitive element PD1 includes a first lower conductive structure LC1, a first photosensitive layer SR1, and a first upper conductive structure UC1′ stacked in sequence. Each second photosensitive element PD2 includes a second lower conductive structure LC2, a second photosensitive layer SR2, and a second upper conductive structure UC2 stacked in sequence. The first lower conductive structure LC1 and the second lower conductive structure LC2 are electrically connected to the active element layer 110.

In this embodiment, the material of the first upper conductive structure UC1′ of the first photosensitive element PD1 is the same as the material of the second upper conductive structure UC2 of the second photosensitive element PD2, and the material of the first lower conductive structure LC1 of the first photosensitive element PD1 is the same as the material of the second lower conductive structure LC2 of the second photosensitive element PD2.

In this embodiment, the first upper conductive structure UC1′ and the second upper conductive structure UC2 include a transparent conductive material, such as indium tin oxide, indium zinc oxide, aluminum tin oxide, aluminum zinc oxide, indium gallium zinc oxide, or a stacked layer of at least two of the above or other materials. The first lower conductive structure LC1 and the second lower conductive structure LC2 include opaque metal electrodes.

A first shielding structure 238 overlaps the first photosensitive element PD1, and does not overlap the second photosensitive element PD2. The first shielding structure 238 is an opaque structure or a semi-transparent structure. In this embodiment, the first shielding structure 238 is a semi-transparent structure and includes molybdenum, aluminum or other materials. The thickness of the first shielding structure 238 is less than 500 nm.

In this embodiment, the first collimating structure 230 is located above the first photosensitive element PD1 and above the second photosensitive element PD2, and the first collimating structure 230 and the first shielding structure 238 include the same metal material. For example, the first collimating structure 230 includes a first light shielding layer 232 and a first anti-reflection layer 234 on the first light shielding layer 232. The first light shielding layer 232 and the first shielding structure 238 include the same metal material, and the first light shielding layer 232 and the first shielding structure 238 are directly connected, and the thickness of the first shielding structure 238 is less than the thickness of the first light shielding layer 232. In this embodiment, the first anti-reflection layer 234 does not overlap the first shielding structure 238. In some embodiments, the first light shielding layer 232 is formed together with the first shielding structure 238, thereby reducing the manufacturing cost of the photosensitive device 40.

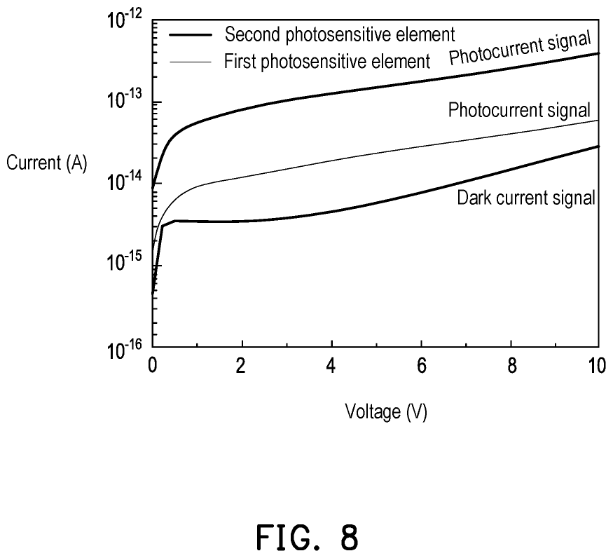

Based on the above, the intensity of the photocurrent signal generated by the first photosensitive element PD1 is smaller than the intensity of the photocurrent signal generated by the second photosensitive element PD2, and the dark current signals of the first photosensitive element PD1 and the second photosensitive element PD2 have the same intensity. The first shielding structure 238 is configured to reduce the signal difference I1 between the photocurrent signal and the dark current signal of the first photosensitive element PD1, so that the signal difference I1 between the photocurrent signal and the dark current signal of the first photosensitive element PD1 is smaller than the signal difference I2 between the photocurrent signal and the dark current signal of the second photosensitive element PD2, as shown in FIG. 8.

In this embodiment, the difference between the signal difference I1 and the signal difference I2 may be used to identify the authenticity of the fingerprint, so that the photosensitive device 40 has an anti-counterfeiting function, and the reliability of fingerprint recognition may be improved by the first photosensitive element PD1 and the second photosensitive element PD2.

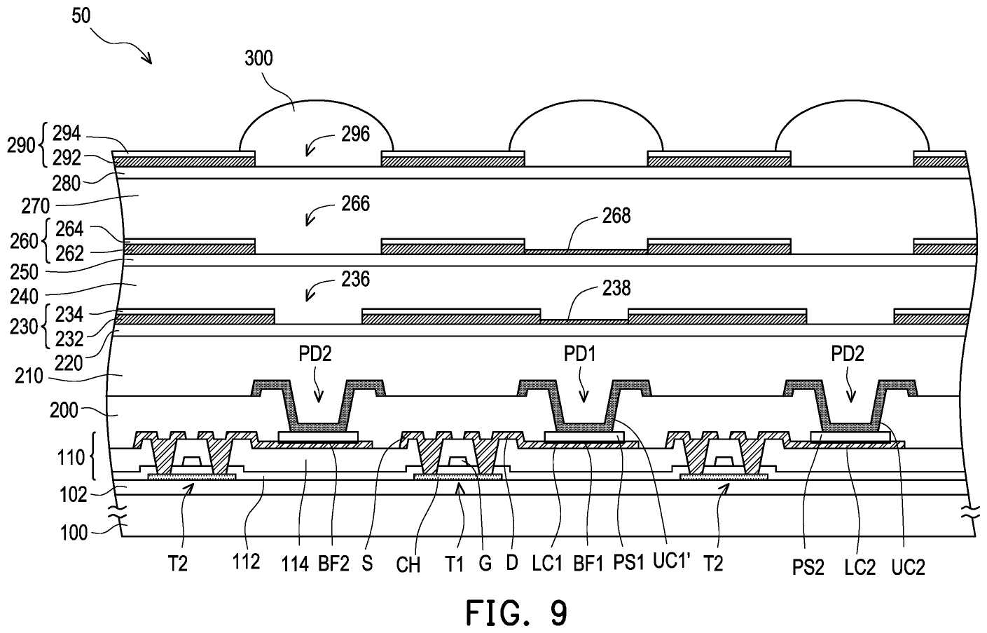

FIG. 9 is a schematic cross-sectional view of a photosensitive device according to an embodiment of the disclosure. It is noted that the embodiment of FIG. 9 uses the reference numerals and a part of the contents of the embodiment of FIG. 7, and the same or similar reference numerals are used to denote the same or similar elements, and the description of the same technical content is omitted. For the description of the omitted part, reference may be made to the foregoing embodiments, and details are not described herein.

The difference between a photosensitive device 50 of FIG. 9 and the photosensitive device 40 of FIG. 7 is that the photosensitive device 50 further includes a second shielding structure 268.

Please refer to FIG. 9. The second shielding structure 268 overlaps the first photosensitive element PD1 and the first shielding structure 238, and does not overlap the second photosensitive element PD2. The second shielding structure 268 is an opaque structure or a semi-transparent structure. In this embodiment, the second shielding structure 268 is a semi-transparent structure and includes molybdenum, aluminum or other materials. The thickness of the second shielding structure 268 is less than 500 nm. In this embodiment, the second shielding structure 268 is farther away from the first photosensitive element PD1 than the first shielding structure 238, and the width of the second shielding structure 268 is greater than the width of the first shielding structure 238.

In this embodiment, the second collimating structure 260 is located above the first photosensitive element PD1 and above the second photosensitive element PD2, and the second collimating structure 260 and the second shielding structure 268 include the same metal material. For example, the second collimating structure 260 includes a second light shielding layer 262 and a second anti-reflection layer 264 on the second light shielding layer 262. The second light shielding layer 262 and the second shielding structure 268 include the same metal material, and the second light shielding layer 262 and the second shielding structure 268 are directly connected, and the thickness of the second shielding structure 268 is less than the thickness of the second light shielding layer 262. In this embodiment, the second anti-reflection layer 264 does not overlap the second shielding structure 268. In some embodiments, the second light shielding layer 262 is formed together with the second shielding structure 268, thereby reducing the manufacturing cost of the photosensitive device 50.

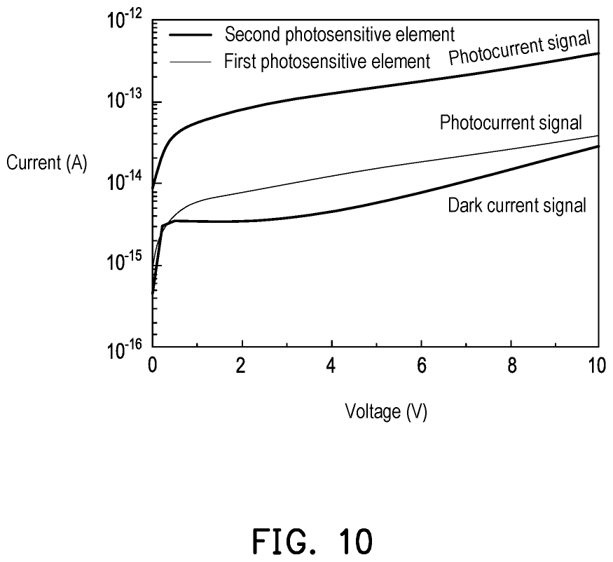

Based on the above, the intensity of the photocurrent signal generated by the first photosensitive element PD1 is smaller than the intensity of the photocurrent signal generated by the second photosensitive element PD2, and the dark current signals of the first photosensitive element PD1 and the second photosensitive element PD2 have the same intensity. The first shielding structure 238 and the second shielding structure 268 are configured to reduce the signal difference I1 between the photocurrent signal and the dark current signal of the first photosensitive element PD1, so that the signal difference I1 between the photocurrent signal and the dark current signal of the first photosensitive element PD1 is smaller than the signal difference I2 between the photocurrent signal and the dark current signal of the second photosensitive element PD2, as shown in FIG. 10.

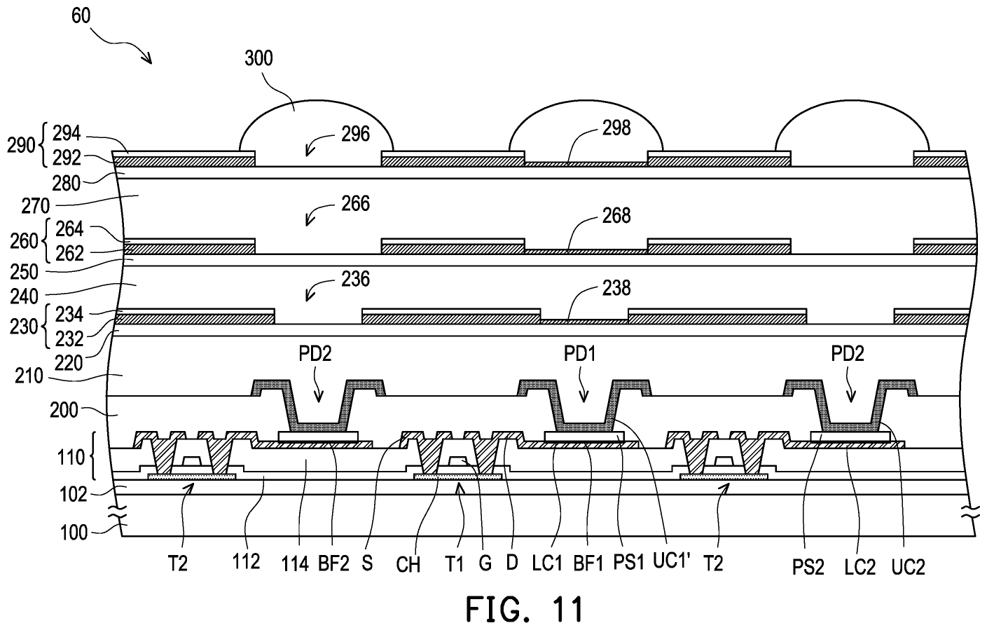

FIG. 11 is a schematic cross-sectional view of a photosensitive device according to an embodiment of the disclosure. It is noted that the embodiment of FIG. 11 uses the reference numerals and a part of the contents of the embodiment of FIG. 9, and the same or similar reference numerals are used to denote the same or similar elements, and the description of the same technical content is omitted. For the description of the omitted part, reference may be made to the foregoing embodiments, and details are not described herein.

The difference between a photosensitive device 60 of FIG. 11 and the photosensitive device 50 of FIG. 9 is that the photosensitive device 60 further includes a third shielding structure 298.

Please refer to FIG. 11. The third shielding structure 298 overlaps the first photosensitive element PD1, the first shielding structure 238 and the second shielding structure 268, and does not overlap the second photosensitive element PD2. The third shielding structure 298 is an opaque structure or a semi-transparent structure. In this embodiment, the third shielding structure 298 is a semi-transparent structure and includes molybdenum, aluminum or other materials. The thickness of the third shielding structure 298 is less than 500 nm. In this embodiment, the third shielding structure 298 is farther away from the first photosensitive element PD1 than the second shielding structure 268, and the width of the third shielding structure 298 is greater than or equal to the width of the second shielding structure 268.

In this embodiment, the third collimating structure 290 is located above the first photosensitive element PD1 and above the second photosensitive element PD2, and the third collimating structure 290 and the third shielding structure 298 include the same metal material. For example, the third collimating structure 290 includes a third light shielding layer 292 and a third anti-reflection layer 294 on the third light shielding layer 292. The third light shielding layer 292 and the third shielding structure 298 include the same metal material, and the third light shielding layer 292 and the third shielding structure 298 are directly connected, and the thickness of the third shielding structure 298 is less than the thickness of the third light shielding layer 292. In this embodiment, the third anti-reflection layer 294 does not overlap the third shielding structure 298. In some embodiments, the third light shielding layer 292 is formed together with the third shielding structure 298, thereby reducing the manufacturing cost of the photosensitive device 60.

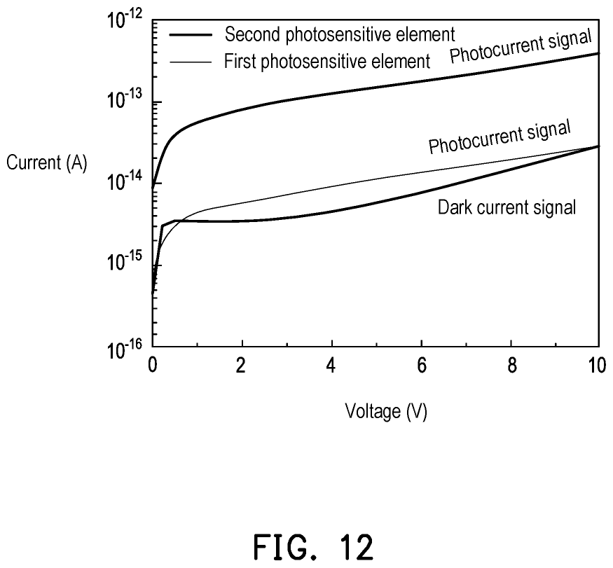

Based on the above, the intensity of the photocurrent signal generated by the first photosensitive element PD1 is smaller than the intensity of the photocurrent signal generated by the second photosensitive element PD2, and the dark current signals of the first photosensitive element PD1 and the second photosensitive element PD2 have the same intensity. The first shielding structure 238, the second shielding structure 268 and the third shielding structure 298 are configured to reduce the signal difference I1 between the photocurrent signal and the dark current signal of the first photosensitive element PD1, so that the signal difference I1 between the photocurrent signal and the dark current signal of the first photosensitive element PD1 is smaller than the signal difference I2 between the photocurrent signal and the dark current signal of the second photosensitive element PD2, as shown in FIG. 12.

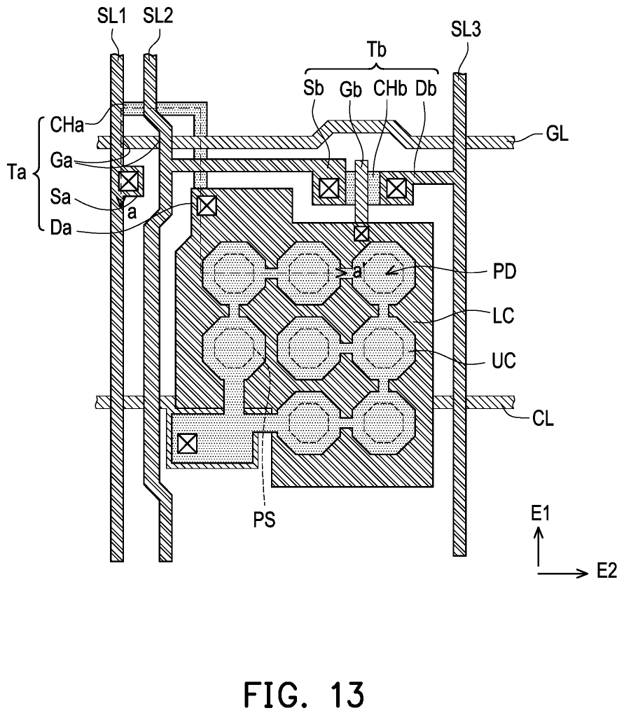

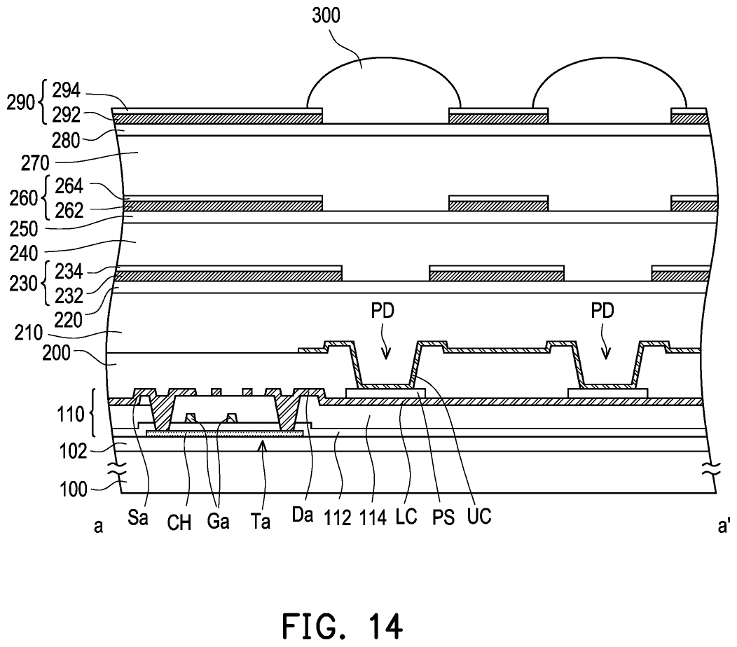

FIG. 13 is a schematic top view of a photosensitive device according to an embodiment of the disclosure. FIG. 14 is a schematic cross-sectional view taken along line a-a′ of FIG. 13. It is noted that the embodiment of FIG. 13 and FIG. 14 uses the reference numerals and a part of the contents of the embodiment of FIG. 1, and the same or similar reference numerals are used to denote the same or similar elements, and the description of the same technical content is omitted. For the description of the omitted part, reference may be made to the foregoing embodiments, and details are not described herein.

In this embodiment, two or more photosensitive elements PD are connected to each other, and one active element Ta and one active element Tb in the active element layer 110 are electrically connected to the two or more photosensitive elements PD. In some embodiments, the photosensitive element PD is the first photosensitive element of the foregoing embodiments, and the active element Ta is the first active element of the foregoing embodiments. In some embodiments, the photosensitive element PD is the second photosensitive element of the foregoing embodiments, and the active element Ta is the second active element of the foregoing embodiments.

The active element layer 110 includes multiple first signal lines SL1, multiple second signal lines SL2, multiple third signal lines SL3, a gate line GL, a common electrode line CL, the active element Ta and the active element Tb. The first signal lines SL1, the second signal lines SL2, and the third signal lines SL3 extend along a first direction E1, and the gate line GL and the common electrode line CL extend along a second direction E2.

The active element Ta includes a gate Ga, a channel CHa, a source Sa, and a drain Da. The channel CHa overlaps the gate Ga, and a gate insulating layer 112 is sandwiched between the channel CHa and the gate Ga. An interlayer dielectric layer 114 is located on the gate Ga and the gate insulating layer 112. The source Sa and the drain Da are located on the interlayer dielectric layer 114 and are electrically connected to the channel CHa through a conductive hole penetrating the gate insulating layer 112 and the interlayer dielectric layer 114. The gate Ga is electrically connected to the gate line GL. The source Sa is electrically connected to the first signal line SL1, and the drain Da is electrically connected to the lower conductive structures LC of the photosensitive elements PD. In this embodiment, the lower conductive structures LC of the photosensitive elements PD are connected to each other. In this embodiment, the lower conductive structure LC of the photosensitive element PD is integrated with the drain Da, but the disclosure is not limited thereto.

The active element Tb includes a gate Gb, a channel CHb, a source Sb, and a drain Db. The channel CHb overlaps the gate Gb, and the gate insulating layer 112 is sandwiched between the channel CHb and the gate Gb. The interlayer dielectric layer 114 is located on the gate Gb and the gate insulating layer 112. The source Sb and the drain Db are located on the interlayer dielectric layer 114 and are electrically connected to the channel CHb through a conductive hole penetrating the gate insulating layer 112 and the interlayer dielectric layer 114. The gate Gb is electrically connected to the lower conductive structures LC of the photosensitive elements PD. The source Sb is electrically connected to the second signal line SL2, and the drain Db is electrically connected to the third signal line SL3.

In this embodiment, the photosensitive layers PS of the photosensitive elements PD are separated from each other. The upper conductive structures UC of the photosensitive elements PD are connected to each other and electrically connected to the common electrode line CL. In addition, a protective layer (not shown) is optionally included between the lower conductive structure LC of the photosensitive element PD and the photosensitive layer PS, and for example, the protective layer is adapted for suppressing the generation of dark current.

To sum up, the embodiments of the disclosure may reduce the difference between the photocurrent signal and the dark current signal of the first photosensitive element without disposing a color filter overlapping the photosensitive element in the photosensitive device. Therefore, the photosensitive device has low manufacturing cost and high reliability.

What is claimed is:

1. A photosensitive device comprising:
a substrate;
an active element layer located above the substrate;
at least one first photosensitive element, wherein each of the at least one first photosensitive element comprises a first lower conductive structure, a first photosensitive layer, and a first upper conductive structure stacked in sequence, and the first lower conductive structure is electrically connected to the active element layer; and
at least one second photosensitive element, wherein each of the at least one second photosensitive element comprises a second lower conductive structure, a second photosensitive layer, and a second upper conductive structure stacked in sequence, and the second lower conductive structure is electrically connected to the active element layer,
wherein the first upper conductive structure comprises an opaque electrode or a semi-transparent electrode, the second upper conductive structure comprises a transparent electrode, and the first upper conductive structure is configured so that a signal difference between a photocurrent signal and a dark current signal of the at least one first photosensitive element is smaller than a signal difference between a photocurrent signal and a dark current signal of the at least one second photosensitive element.

2. The photosensitive device according to claim 1, wherein the at least one first photosensitive element comprises a plurality of first photosensitive elements, and one first active element in the active element layer is electrically connected to two or more of the first photosensitive elements.

3. The photosensitive device according to claim 1, wherein the at least one first photosensitive element comprises a plurality of first photosensitive elements, and each of the first photosensitive elements is electrically connected to a corresponding first active element in the active element layer.

4. The photosensitive device according to claim 1, further comprising:
a collimating structure located above the at least one first photosensitive element and above the at least one second photosensitive element, wherein the collimating structure has a plurality of openings overlapping the at least one first photosensitive element and the at least one second photosensitive element; and
a plurality of lens elements located above the at least one first photosensitive element and the at least one second photosensitive element.

5. The photosensitive device according to claim 1, wherein the first lower conductive structure and the second lower conductive structure comprise a same material.

6. The photosensitive device according to claim 1, wherein the first lower conductive structure comprises a transparent electrode, and the second lower conductive structure comprises an opaque electrode.

7. The photosensitive device according to claim 1, wherein under a same amount of light, an intensity of the photocurrent signal generated by the at least one first photosensitive element is smaller than an intensity of the photocurrent generated by the at least one second photosensitive element.

8. A photosensitive device comprising:
a substrate;
an active element layer located above the substrate;
at least one first photosensitive element, wherein each of the at least one first photosensitive element comprises a first lower conductive structure, a first photosensitive layer, and a first upper conductive structure stacked in sequence, and the first lower conductive structure is electrically connected to the active element layer; and
at least one second photosensitive element, wherein each of the at least one second photosensitive element comprises a second lower conductive structure, a second photosensitive layer, and a second upper conductive structure stacked in sequence, and the second lower conductive structure is electrically connected to the active element layer,
wherein the first lower conductive structure comprises a transparent electrode, the second lower conductive structure comprises an opaque electrode, and the first lower conductive structure is configured so that a signal difference between a photocurrent signal and a dark current signal of the at least one first photosensitive element is smaller than a signal difference between a photocurrent signal and a dark current signal of the at least one second photosensitive element.

9. The photosensitive device according to claim 8, wherein each of the at least one second photosensitive element further comprises:
a protective layer located between the second photosensitive layer and the second lower conductive structure, wherein a material of the second lower conductive structure comprises metal, and a material of the first lower conductive structure comprises metal oxide.

10. The photosensitive device according to claim 8, wherein the active element layer comprises:
a first active element electrically connected to the at least one first photosensitive element; and
a second active element electrically connected to the at least one second photosensitive element.

11. The photosensitive device according to claim 8, wherein the first upper conductive structure and the second upper conductive structure comprise a same material.

12. The photosensitive device according to claim 8, wherein the first upper conductive structure comprises an opaque electrode or a semi-transparent electrode, and the second upper conductive structure comprises a transparent electrode.

13. The photosensitive device according to claim 8, wherein the dark current signal of the at least one first photosensitive element is greater than the dark current signal of the at least one second photosensitive element.

14. A photosensitive device comprising:
a substrate;
an active element layer located above the substrate;
at least one first photosensitive element, wherein each of the at least one first photosensitive element comprises a first lower conductive structure, a first photosensitive layer, and a first upper conductive structure stacked in sequence, and the first lower conductive structure is electrically connected to the active element layer;
at least one second photosensitive element, wherein each of the at least one second photosensitive element comprises a second lower conductive structure, a second photosensitive layer, and a second upper conductive structure stacked in sequence, and the second lower conductive structure is electrically connected to the active element layer; and
a first shielding structure which is an opaque structure or a semi-transparent structure, wherein the first shielding structure overlaps the at least one first photosensitive element and does not overlap the at least one second photosensitive element,
wherein the first shielding structure is configured so that a signal difference between a photocurrent signal and a dark current signal of the at least one first photosensitive element is smaller than a signal difference between a photocurrent signal and a dark current signal of the at least one second photosensitive element.

15. The photosensitive device according to claim 14, further comprising:
a first collimating structure located above the at least one first photosensitive element and above the at least one second photosensitive element, wherein the first collimating structure and the first shielding structure comprise a same metal material.

16. The photosensitive device according to claim 15, wherein the first collimating structure comprises:
a light shielding layer; and
an anti-reflection layer which is located on the light shielding layer and does not overlap the first shielding structure.

17. The photosensitive device according to claim 16, wherein the light shielding layer is directly connected to the first shielding structure, and a thickness of the first shielding structure is less than a thickness of the light shielding layer.

18. The photosensitive device according to claim 16, further comprising:
a second shielding structure which is an opaque structure or a transparent structure, overlaps the first shielding structure and does not overlap the at least one second photosensitive element; and
a second collimating structure which overlaps the first collimating structure, wherein the second collimating structure is directly connected to the second shielding structure.

19. The photosensitive device according to claim 18, wherein the second shielding structure is farther away from the at least one first photosensitive element than the first shielding structure, and a width of the second shielding structure is greater than a width of the first shielding structure.
